(19) United States
(12) Patent Application Publication
(10) Pub. No.: US 2023/0305244 A1
(43) Pub. Date: Sep. 28, 2023

(54) HIGH DENSITY OPTICAL/ELECTRICAL INTERCONNECTION ARRANGEMENT WITH HIGH THERMAL EFFICIENCY

(71) Applicant: Aayuna Inc., Allentown, PA (US)

(72) Inventors: Kalpendu Shastri, Orefield, PA (US); Soham Pathak, Allentown, PA (US); Bipin D. Dama, Bridgewater, NJ (US); Sriram Tyagarajan, Macungie, PA (US); Anujit Shastri, San Francisco, CA (US); Rao Yelamarty, Allentown, PA (US)

(73) Assignee: Aayuna Inc., Allentown, PA (US)

(21) Appl. No.: 18/018,932

(22) PCT Filed: Aug. 12, 2021
(86) PCT No.: PCT/US2021/045693

§ 371 Date: Jan. 31, 2023

Related U.S. Application Data
(60) Provisional application No. 63/065,848, filed on Aug. 14, 2020.

(51) Int. Cl. G02B 6/42

(52) U.S. Cl. CPC G02B 6/4269; G02B 6/428; G02B 6/4224

(57) ABSTRACT

A configuration of both optical and electronic integrated circuits is formed upon a single substrate in a side-by-side arrangement, with minimal interposing elements required to direct the flow of electronic signals from one IC to another. The various sets of optical connections (typically, fiber arrays that are connected to components beyond the interconnect) are disposed around the outer periphery of the interconnect in a manner that allows for efficient access. Oriented with the substrate as top layer in stack, a heatsink may be coupled directly to exposed substrate surface and provide an efficient path for heat transfer away from the interconnection assembly.

### CROSS-REFERENCE TO RELATED APPLICATIONS

This application claims the benefit of priority from U.S. Provisional Application No. 63/065,848, filed Aug. 14, 2020 and herein incorporated by reference.

### TECHNICAL FIELD

The present invention relates to the provision of reliable, economical interconnections between optical and electronic integrated circuits, particularly arrangements for providing high density interconnections with high thermal efficiency.

### BACKGROUND OF THE INVENTION

Technical advances such as increases in connectivity technologies and the growth of processing loads are generating ever-increasing demands on bandwidth and transmission speeds. Data centers, for example, may utilize optical-based interconnections between servers, racks, and boards. Wide adoption of such photonics-based links places demands on increasing the efficiency and reliability of the electronic-to-optic connections, and will require continued efforts in lowering power consumption and increasing bandwidth throughput (where these two goals are obviously at odds with one another).

Progress has been made with respect to the integration of photonics on silicon, and integration of chips on interposers for standard IC packaging. Going forward, highly-integrated optical modules in combination with necessary electronics (modulator drivers, transimpedance amplifiers, clock/data recovery circuitry, etc.) will need to facilitate thermal energy conduction while also providing low power, high bandwidth performance.

### SUMMARY OF THE INVENTION

The limitations remaining in the art are addressed by the present invention, which relates to the provision of reliable, economical interconnections between optical and electronic integrated circuits, particularly arrangements for providing high density interconnections with high thermal efficiency.

In accordance with the principles of the present invention, a configuration of both optical and electronic integrated circuits is formed upon a single substrate in a side-by-side arrangement, with minimal interposing elements required to direct the flow of electronic signals from one IC to another. The various sets of optical connections (typically, fiber arrays that are connected to components beyond the interconnect) are disposed around the outer periphery of the interconnect in a manner that allows for efficient access.

Oriented with the substrate as top layer in stack, a heatsink may be coupled directly to exposed substrate surface and provide an efficient path for heat transfer away from the interconnection assembly.

In an exemplary embodiment, the present invention takes the form of a high density optical-electrical interconnection arrangement including a substrate formed of a material exhibiting a high CTE to expedite heat transfer (typically silicon), with at least one electrical integrated circuit (EIC) disposed on the substrate and positioned in a central region of the substrate. A plurality of optical integrated circuits (OICs) are also disposed on the substrate and positioned to surround the EIC to form a side-by-side configuration, each OIC including an optical connection array and an electrical connection array. Preferably, each OIC is oriented such that the optical connection array is disposed near an edge of the substrate and the electrical connection array disposed adjacent to the at least one EIC. The interconnection also includes a plurality of bridging electrical connection modules, each bridging electrical connection module disposed to straddle an OIC and an EIC so as to contact the electrical connection array of the OIC and an associated electrical connection array on the at least one EIC. A heatsink is attached to the opposing surface of the substrate, providing efficient heat transfer away from the interconnection arrangement.

Other and further embodiments and aspects of the present invention will become apparent during the course of the following discussion and by reference to the accompanying drawings.

### BRIEF DESCRIPTION OF THE DRAWINGS

Referring now to the drawings, where like numerals represent like parts in several views:

FIG. 1 is a simplified block diagram view of an exemplary interconnection arrangement formed in accordance with the present invention;

FIG. 2 is a top view of the substrate portion of the interconnection arrangement, illustrating an exemplary set of alignment fiducials that may be used;

FIG. 3 is alternative configuration of the substrate, illustrating vision markers that may be used in a vision-based alignment method;

FIG. 4 shows another vision-based alignment arrangement that may be used in accordance with the principles of the present invention;

FIG. 5 illustrates an exemplary arrangement of OICs in alignment with a pair of EICs, all of the integrated circuits being disposed upon and attached to a common substrate;

FIG. 6 depicts a starting point in the process of assembling a high density interconnection arrangement in accordance with the principles of the present invention;

FIG. 7 illustrates a following step of placing the EICs on the substrate (in proper, aligned, locations);

FIG. 8 then illustrates the step of placing a plurality of OICs around the EICs (in a side-by-side arrangement);

FIG. 9 shows a step of positioning an electrical connection interposer over an exposed areas of the EICs, where it is evident that the thickness of the interposer is selected to form a planar surface with the OICs;

FIG. 10 shows the placement of bridging EICs to “straddle” an OIC electrical connection area and associated portion of the interposer;

FIG. 11 illustrates a complete interconnection assembly, based upon the configuration of FIG. 10 and including a heatsink (positioned on the top surface of the “inverted” interconnection arrangement) and additional electrical connections to external components through an interface;

FIG. 12 depicts an alternative arrangement where “thin” OICs are used, avoiding the need to include an interposer to form a planar configuration;

FIG. 13 shows the placement of the bridging EICs so as to directly connect the thin OICs with the EICs;

FIG. 14 illustrates a complete interconnection assembly, based upon the configuration of FIG. 13 and including a heatsink (positioned on the top surface of the “inverted” interconnection arrangement) and additional electrical connections to external components through an interface;

FIG. 15 shows an alternative embodiment of the assembly of FIG. 14, in this case including a substrate that is wide enough to “overhang” the locations for the optical signal array connectors on the OICs;

FIG. 16 depicts yet another alternative to the assembly of FIG. 14, where in this case a ceramic substrate is included between the external electrical connection interface (BGA) and a host communication board; and

FIG. 17 shows an alternative to the arrangement of FIG. 16, in this case using a socket component to releasably connect the ceramic substrate to the host board.

### DETAILED DESCRIPTION

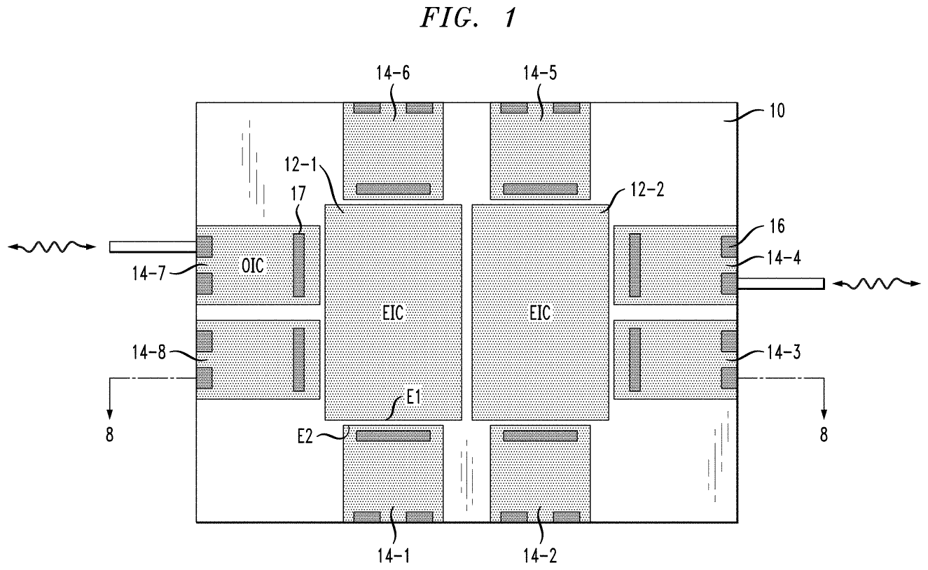

Wide adoption of photonics links depends on reliably connecting optics to electronics through an interconnect system that provides low power consumption and high bandwidth throughput, and which can be manufactured using high volume and low cost manufacturing techniques. Serial link performance is limited by the channel electrical bandwidth and the electronic components. In order to resolve the inter-symbol interference (ISI) problems caused by bandwidth limitations, there is a need to bring all electrical components as close together as possible. Additionally, configurations that avoid the need for wirebond connections are preferred. The basic arrangement of EICs and OICs as shown in FIG. 1 can be aligned and interconnected in a manner that addresses all of these concerns.

FIG. 1 is a simplified block diagram view of an exemplary interconnection arrangement of the present invention that includes several optical integrated circuits (OICs) and electronic integrated circuits (EICs) supported in a side-by-side arrangement on a single substrate. In particular, FIG. 1 illustrates a common silicon substrate 10 used to support a pair of EICs 12-1 and 12-2 positioned on a central area of a top surface 10T of substrate 10. In the top view of FIG. 1, a set of OICs 14-1 through 14-8 is shown as disposed around the periphery of substrate 10 such that each OIC 14 is adjacent to an exposed edge of either EIC 12-1 or 12-2. OICs 14 are electrically connected to EICs 12-1, 12-2 in a manner described in detail hereinbelow that provides efficient, low-cost and high speed interconnection. The particular arrangement of two EICs and eight OICs as shown in FIG. 1 is considered to be exemplary only; in general, the principles of the present invention are useful for any number of EICs surrounded by an associated set of OICs in a planar (side-by-side) manner to allow for efficient interconnection, as well as relatively short paths for directing heat away from the assembly (as discussed in detail below).

Each OIC 14 is shown as including an optical fiber connection region 16, which is used to couple an optical fiber array (or other type of lightwave supporting medium) to OIC 14 using one of several technologies known in the art. It is to be understood that while OICs 14 are shown as including optical fiber array interconnections, this is exemplary only and in other arrangements these OICs may provide “free space” optical outputs, or be coupled to various types of optical waveguides. Each OIC 14 also includes an electrical signal connection region 17. As will be discussed in detail below, “bridging” electrical connection ICs provide connection between connection regions 17 on OICs 14 with paired electrical connection areas on EICs 12.

While a gap is shown between a given edge of an EIC 12 (shown as E1 in FIG. 1), and a given edge of an OIC 14 (shown as E2 in FIG. 1), it is to be understood that once EICs 12 are properly positioned, OICs 14 may be disposed to abut the edges of the respective EICs. Inasmuch as the edges of EIC 12 are known to be straight and even (since they are created by a standard integrated circuit “dicing” operation), these edges may be used as alignment features for proper positioning of OICs 14. Once OICs 14 are positioned on substrate 10, the collection of EICs 12 and OICs 14 may be interconnected in a manner that is based on the use of optical input and output signals, with the electronics used internally to efficiently interconnect the desired input and output optical signal paths. EICs 12 typically include a “serializer/deserializer” (SERDES) component for interleaving or de-interleaving separate electrical signal paths, directing signals between optical inputs and outputs.

In most cases, OICs 14 also include an active opto-electronic component that either converts an applied electrical signal (from an associated EIC 12) into an optical output signal, and/or an active opto-electronic component that converts a received optical signal (such as from attached fibers) into an electrical output (for example, a data or communication signal) that is then passed along to the associated EIC 12. OICs 14 may also comprise passive optical components (e.g., waveguides, lenses, isolators, etc.) and additional active components such as modulators or tunable filters. The specific elements included in OICs 14 may vary from application to application, and are not considered to be germane to the subject matter of the present invention.

The view as shown in FIG. 1 thus depicts an exemplary “layer” within an interconnection system that handles optical input/output, as well as optical/electrical conversions, and is considered as a backbone layer in providing a high density type of interconnection between optics and electronics with minimal heat generation.

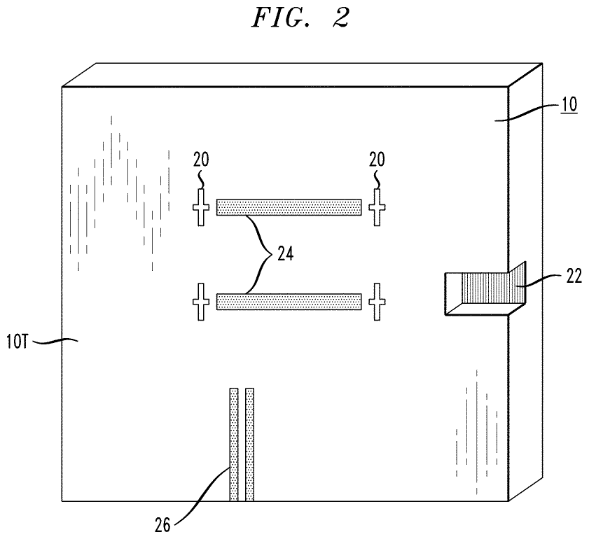

One criteria for forming such a high density, low thermal interconnection arrangement is ensuring alignment between the various ICs so as to maintain proper coupling between the associated electrical and optical signal paths as mentioned above, as well as coupling optical signals into and out of fibers (or other waveguiding elements) disposed within connection region 16. FIGS. 2-5 depict various examples of alignment techniques that may be used to first position and “register” the EICs at defined locations on the substrate surface, and thereafter position the OICs on the substrate such that the electrical interconnections between the OICs and EICs will be automatically aligned.

FIG. 2 is a top view of substrate 10, prior to being populated with EICs 12 and OICs 14, and illustrates alignment fiducials 20 that are formed in top surface 10T of substrate 10. Alignment fiducials 20 may be used to ensure proper positioning of EICs 12 on surface 10T of substrate 10. Also shown in FIG. 2 is a set of etched “pockets” 22 (formed using deep RIE, for example) created to a specific depth below top surface 10T, and used to delineate the properly-aligned positions for each of OICs 14. Instead of (or in addition to) these features, sets of etched/laser written bond lines 24, 26 may be formed on top surface 10T and filled with an appropriate bonding material before placing EICs 12 and OICs 14 in their defined locations. Bond lines (slots) 24, 26 are formed as “zero micron” bond lines so as to maintain the defined integrated circuit heights for EICs 12 and OICs 14 that are to be positioned on the adhesive material filling the slots. In one embodiment, bond lines 26 may be disposed within the bottom surface of the DRIE pockets 22 to physically secure the positioning of OICs 14.

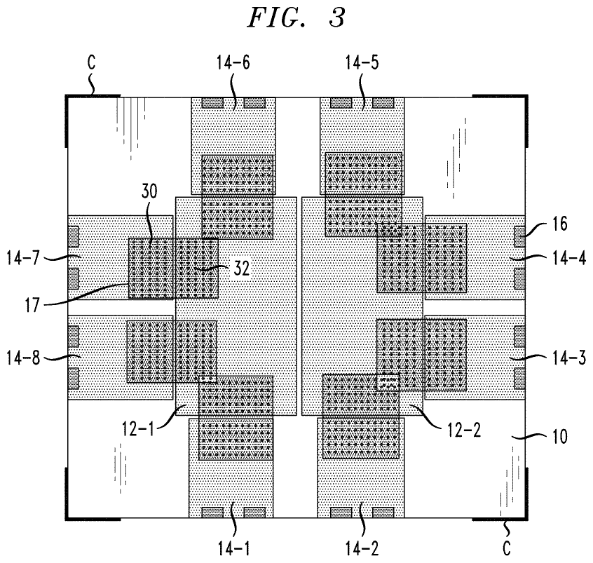

Alternatively, a vision system may be used to align the electrical contact elements formed on the top surfaces of EICs 12 and OICs 14. These contact elements may take the form of under bump metallization (UBM) or copper pillars, for example, and shown as contact elements 30 (formed within defined electrical signal connection region 17) on an exemplary OIC 14-7 and contact elements 32 on associated EIC 12-1. In using a vision system for this purpose, additional registration, perhaps keying off corners C of substrate 10 as shown in FIG. 3, may be used.

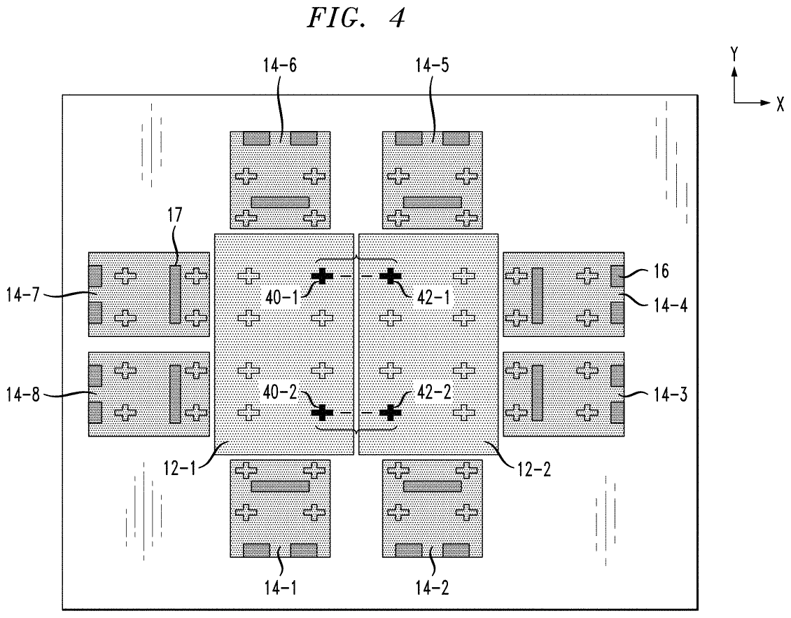

FIG. 4 illustrates an alternative vision-based alignment arrangement that may be used to provide accurate alignment between EICs 12 and OICs 14 in accordance with the principles of the present invention. In particular, the configuration as shown in FIG. 4 is particularly well-suited for arrangements where these various ICs include high count bond pad locations on these elements.

Turning to the details of FIG. 4, a first plurality of alignment features 40 are formed on EIC 12-1 and a second plurality of alignment features 42 are formed on EIC 12-2. A vision system (not shown) may thus be used to ensure that features 40 and 42 align in both the x-axis and y-axis directions, as shown. Presuming that EIC 12-1 is first placed in position on substrate 10, EIC 12-2 is positioned (using a conventional vision system, for example) so that alignment features 42 are collinear with their respective alignment features on EIC 12-1. That is, for this particular configuration of FIG. 4, alignment feature 42-1 on EIC 12-2 is aligned with alignment feature 40-1 on EIC 12-1 (in both the x-axis direction and y-axis direction), and alignment feature 42-2 on EIC 12-2 is aligned with alignment feature 40-2 on EIC 12-1.

Once EICs 12-1 and 12-2 are properly positioned and aligned with respect to each other, the various OICs 14 are positioned on substrate 10 in alignment with their associated EICs 12, here using alignment features formed on the top surfaces of OICs 14. As shown in FIG. 5 with respect to OIC 14-7, alignment features 44 are used to properly position OIC 14-7 with its associated EIC 12-1. Here, a pair of alignment features 44-1 and 44-2 formed on OIC 14-7 are aligned in x-y plane with alignment features 40-3 and 40-4 formed on EIC 12-1. While not particularly enumerated, each OIC 14 is similarly aligned with a designated location around the periphery of either EIC 12-1 or EIC 12-2.

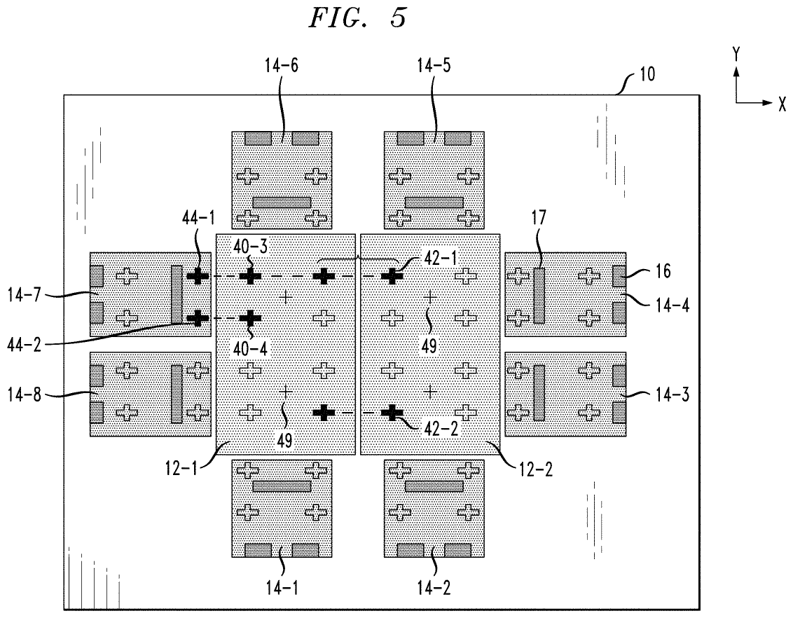

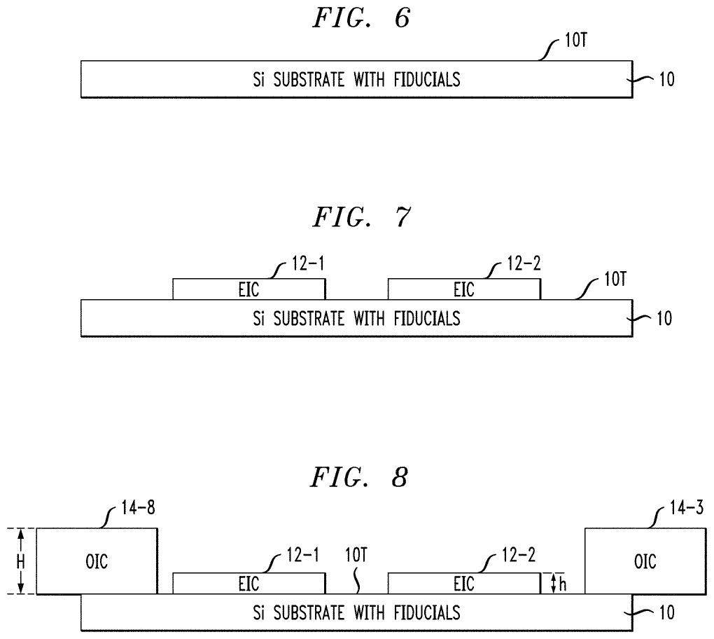

FIGS. 6-8 illustrate, in a cross-sectional view, a set of steps that correspond to the placement of EICs 12 and OICs 14 on substrate 10. The attachment of these ICs to substrate 10 may utilize the mechanical type of fiducials shown in FIG. 2, the contact element alignments shown in FIG. 3, the visual alignment features of FIGS. 4 and 5, or any other system suitable for ensuring the integrity of the electrical and optical signal paths across the substrate.

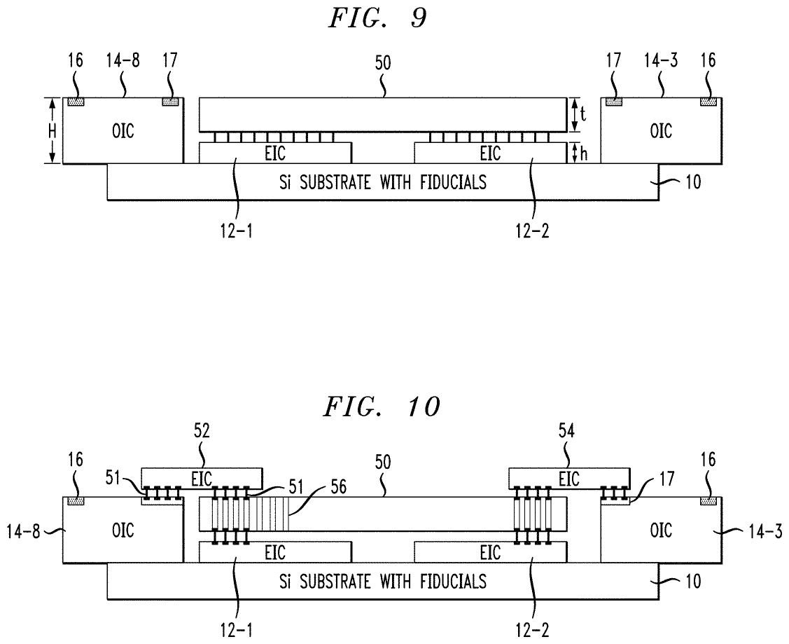

FIG. 6 shows the starting point of the assembly process, beginning with substrate 10. In most cases, substrate 10 is formed of silicon or a similar material that may be processed using well-known CMOS fabrication techniques to create any surface features necessary to support alignment. Moreover, as will be discussed below, silicon has a relatively high CTE and allows for an efficient transfer of heat away from the attached ICs. FIG. 7 illustrates the following steps of placing EICs 12-1 and 12-2 on top surface 10T of substrate 10 (using any of the described alignment techniques, for example), with FIG. 8 illustrating the subsequent placement of OICs 14 around the exposed sides of EICs 12, in a manner where the OICs are aligned with their associated EICs. The view of FIG. 8 is taken along line 8-8 of FIG. 1 and thus particularly illustrates OIC 14-8 as positioned in alignment with EIC 12-1, and OIC 14-3 as positioned in alignment with EIC 12-2.

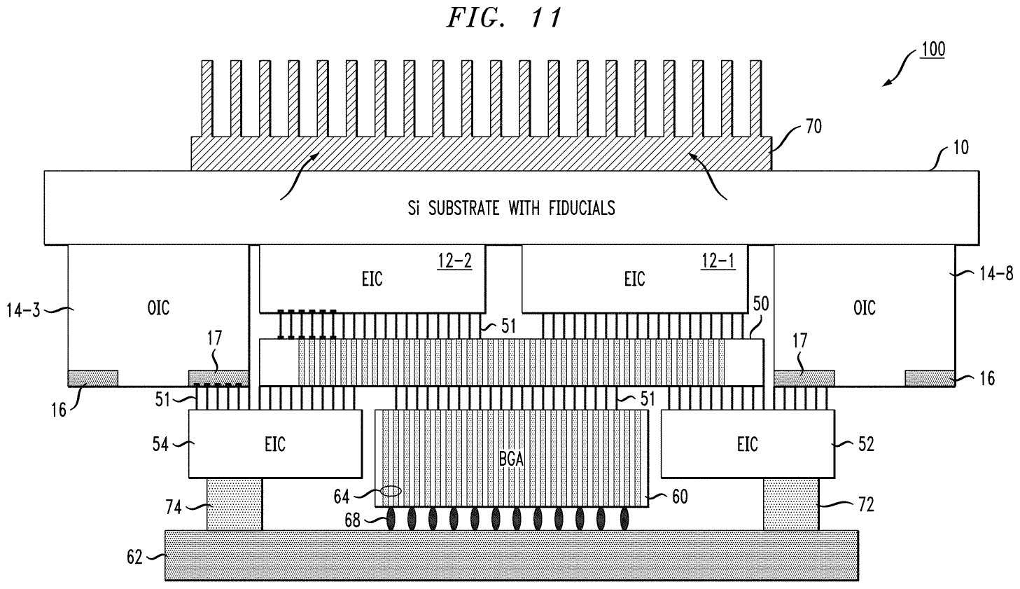

In accordance with the principles of the present invention, “bridging EICs” are positioned to straddle an adjacent pair of EIC 12 and OIC 14, providing electrical connections without the need for wirebonds (or additional substrate processing to form a multi-layer substrate with internal connection lines and vias). FIGS. 9 and 10 illustrate exemplary processing steps for positioning of bridging EICs in accordance with the principles of the present invention. Referring back to FIG. 8, it is shown that typical OICs are “thicker” than their EIC counterparts. In this illustration, OICs 14 are shown to exhibit a height H, as compared to a height h of EICs 12.

Therefore, in order to maintain planarity within the interconnection system, an interposer 50 is shown in FIG. 9 as positioned over EICs 12, where interposer 50 is formed of a designed thickness t such that the “stacked” combination of EICs 12 and interposer 50 is the same as the height H of OICs 14. Said another way, interposer 50 is formed of thickness that provides a planar reference with the top surface of OICs 14. Interposer 50 may be formed of silicon, glass, or any other appropriate insulating (dielectric) material. Any of the above-described alignment systems may be used to ensure accurate placement of interposer 50 on EICs 12. For example, FIG. 5 shows a pair of alignment features 49 that are aligned with features on interposer 50 so that the through-vias on interposer 50 are aligned with the electrical contact pads (not shown) on a top surface of EICs 12.

Once this planarity is achieved, bridging EICs are positioned as shown in FIG. 10 to overlap the electrical signal connection areas of mating OICs and EICs. In this cut-away side view of FIG. 10, a bridging EIC 52 is shown as providing the electrical connection between OIC 14-8 and EIC 12-1, while bridging EIC 54 provides electrical connection between OIC 14-3 and EIC 12-2. While not explicitly shown in this cut-away side view, it is to be understood that a bridging EIC is disposed to overlap electrical connection regions of each OIC 14 and its associated EIC 12. Bridging EICs may include active electronic circuits (such as modulators, TIAs, etc.), or alternatively these elements may be formed within EICs 12. Interposer 50 is shown as including a set of conductive vias 56 that are disposed through the thickness of interposer 50 and used to provide the electrical signal paths between EICs 12 and the bridging EICs.

Advantageously, a relatively high density connection configuration may be used in accordance with the teachings of the present invention to provide the electrical signal interconnections between EICs 12 and OICs 14 necessary for high data rate applications. Shown in FIG. 10 is a specific embodiment where copper pillars 51 are used for forming electrical signal paths through the combination of interposer 50 (vias 56) and bridging EICs 52, 54. Copper pillar connection arrays may be formed to exhibit a spacing (pitch) as close as 80 μm, thus providing the desired high density connection. Copper pillars are only one exemplary type of high density connection that may utilized in this manner in the assemblies of the present invention, micro-bump arrays and UMBs are also choices well-suited for this interconnection.

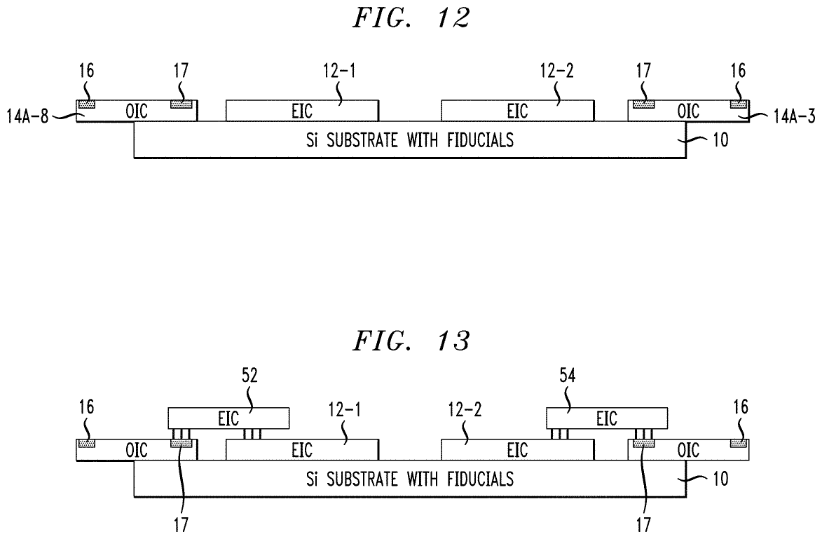

FIG. 11 illustrates an exemplary interconnection assembly 100 formed in accordance with the principles of the present invention and based upon the initial assembly of the components as shown in FIG. 10. In this view of the final assembly, the combination of substrate 10 with EICs 12 and OICs 14 is oriented “upside-down” with respect to the various illustrations discussed above, with substrate 10 positioned as the top-most element in the assembly. Also included in interconnection assembly 100 is a ball grid array (BGA) 60 (or similar interconnection element, such as a socket) that is disposed on interposer 50 and used as an interface to provide an electrical signal connections between interconnection assembly 100 and external communication systems. In most cases, BGA 60 is used to bring “power” and “ground” electrical connections interconnection assembly 100, as well as provide a path for low-speed signals. BGA 60 is shown as terminating on a “host” printed circuit board (PCB) 62, which serves as the source for the power/ground and low speed inputs to BGA 60.

In accordance with these operations, BGA 60 typically exhibits a lower density of connections than copper pillar (or UMB or micro-bump) connections 51 used within the interconnection of the various EICs and OICs discussed above. Indeed, an exemplary BGA 60 may have pitch on the order of 800 μm. BGA 60 generally consists of a silicon member that is fabricated to include a plurality of through-silicon vias (TSVs) 64, with a plurality of high density (e.g., copper pillar) connections 51 formed on top surface 60T of BGA 60 at upper termination locations of TSVs 64 and used to provide electrical connection to EICs 12-1 and 12-2. Other suitable materials, such as glass or other dielectric, may be used in the implementation of BGA 60.

A plurality of solder balls 68 are disposed across the lower surface 60L of BGA 60 at the termination of TSVs 64, and are used as the electrical connection mechanism between lower surface 60L of BGA 60 and host PCB 62. Again, this is considered to be only one example of a variety of different contact configurations for use as an electrical signal interface between BGA 60 and PCB 62. The type of contact may be selected based on the interconnect density, thermal requirements, and the like.

As mentioned above, an advantage of the low-profile, upside-down oriented interconnection assembly 100 is that heat generated by operation of the OICs and EICs may be quickly and efficiently removed along relatively short heat transfer paths. In particular, interconnection assembly 100 is shown as including a heatsink 70 that is directly positioned over and attached to the exposed bottom surface 10B of substrate 10. Heatsink 70 may comprise an air-cooled or liquid-cooled component, both being well-known in the art. Advantageously, this “upside-down” orientation of interconnection assembly 100 (with respect to conventional prior art arrangements) provides for efficient heat transfer directly through substrate 10 and into heatsink 70. It is contemplated that if substrate 10 is relatively thin in its final form (as compared to prior art arrangements), the transfer of heat away from the interconnection assembly is even more efficient.

Shown in phantom in FIG. 11 are additional heatsink elements 72, 74 that may be disposed between bridging EICs 52, 54 and host PCB 62. Here, heatsink element 72 is disposed between bridging EIC 52 and host PCB 62, while heatsink element 74 is disposed between bridging EIC 54 and host PCB 62. In certain applications (e.g., very high density, very high speed, or both), these bridging EICs may generate a substantial amount of heat and the inclusion of heatsink elements 72, 74 further ensures the reliable operation of EICs 12 and OICs 14 under high power conditions.

An alternative embodiment of the present invention is based upon the use of relatively “thin” OICs 14 that are formed to exhibit essentially the same thickness as EICs 12 and thus eliminate the need to include an interposer (such as interposer 50 as shown in FIG. 11, for example) to provide a planar surface for electrical interconnections. FIG. 12 depicts a step in an assembly process where thin OICs 14A are used in combination with EICs 12 to create a low-profile, planar side-by-side arrangement of EICs 12 and OICs 14. Similar to FIGS. 6-11, FIG. 12 is a cut-away side view, which in this case illustrates the positioning of a thin OIC 14A-8 adjacent to EIC 12-1 and a thin OIC 14A-3 adjacent to EIC 12-2. It is to be understood that all of the OICs used in this embodiment exhibit the same thin profile and thus form a planar connection surface in combination with EICs 12-1 and 12-2.

Without the need for an interposer, bridging EICs 52, 54 may be directed connected between OICs 14A and EICs 12. FIG. 13 illustrates the step in the assembly process where the bridging EICs are positioned, and in this case illustrates the use of copper pillar interconnects 51 between the components. As with the embodiment described above, the inclusion of bridging EICs 52, 54 eliminates the need to use wirebond connections between EICs 12 and OICs 14A, where the wirebonds are known to impact the operating speed of the electronics.

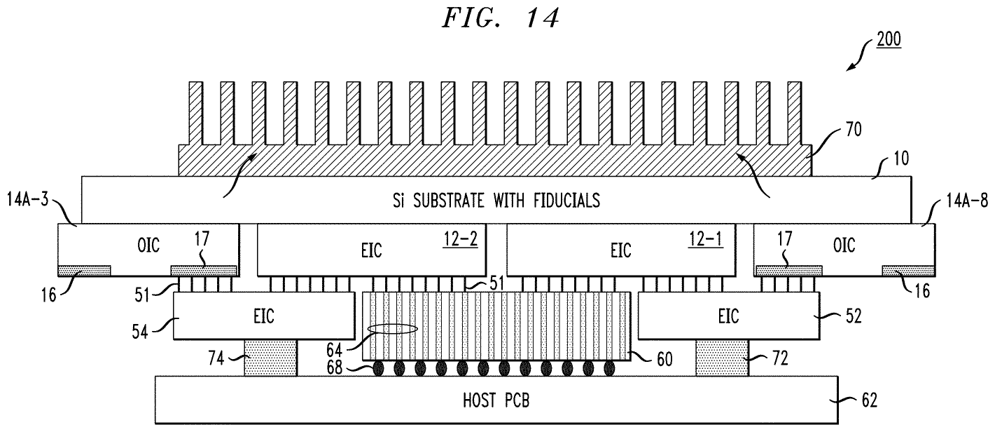

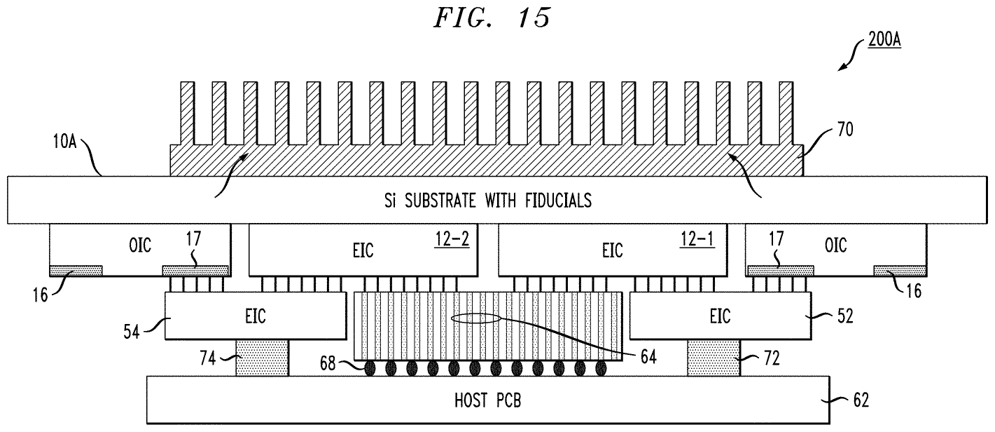

FIG. 14 illustrates an alternative embodiment of the present invention, shown as interconnection assembly 200, which is based upon the use of configuration of FIG. 13 to utilize relatively “thin” OICs 14A that are coplanar with EICs 12. Interconnection assembly 200 is considered to be somewhat simplified, in comparison to assembly 100 of FIG. 11, based upon presented planarity of EICs 12 and OICs 14A. Looking at the particulars of FIG. 14, BGA 60 is directly placed upon and electrically connected to EICs 12 (using copper pillars 51). By virtue of eliminating the interposer in this embodiment, the electrical signal path between EICs 12 and host PCB 62 (via TSVs 64 within BGA 60) is reduced, which allows for the transmission rate to be increased (with respect to the arrangement of interconnection assembly 100).

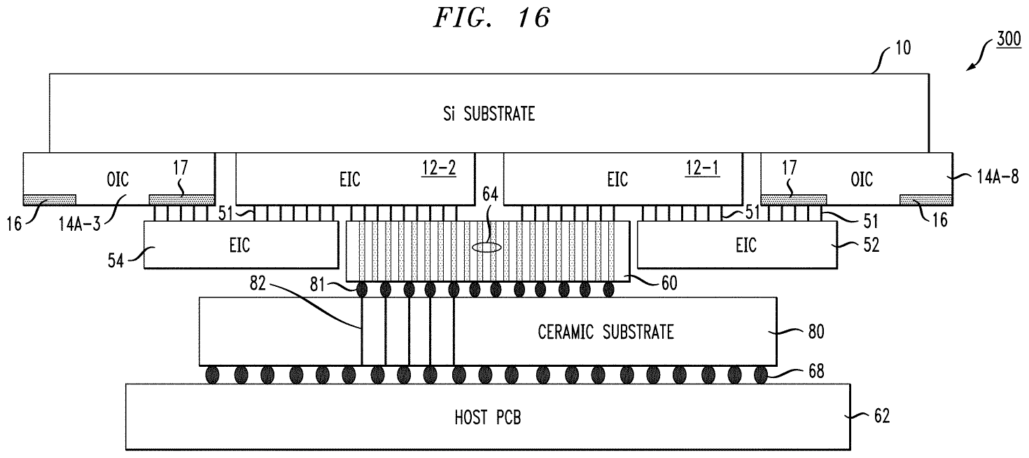

The arrangement of FIG. 15 is a slight variation of assembly 200 of FIG. 14 (and is referred to as interconnection assembly 200A). In this case, the substrate (referred to here as substrate 10A) is sized to over-hang optical I/O connection regions 16 on OICs 14A. There may be situations where it is desirable to ensure that the fiber arrays attached to regions 16 remain protected (covered) by substrate 10A, and the arrangement shown in FIG. 15 meets this need. The remaining elements of interconnection assembly 200A are essentially the same as those discussed above in association with FIG. 14 and function in the same manner to form a high speed, low power interconnection fabric.

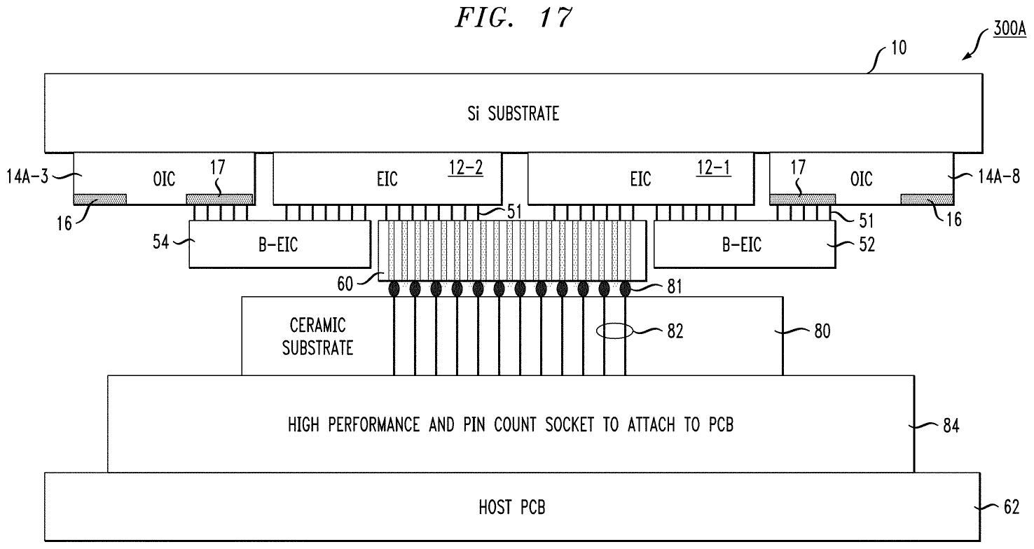

FIG. 16 illustrates yet another embodiment of the present invention. In this case, an interconnection assembly 300 is formed to include a ceramic substrate 80 that is disposed between BGA 60 and host PCB 62. Here, ceramic substrate 80 (which exhibits a coefficient of thermal expansion (CTE) similar to silicon) is used provide a degree of flexibility in the thermo-mechanical properties of assembly 300. In particular and in comparison to interconnection assembly 200 of FIG. 14, interconnection assembly 300 may use shorter and higher-density micro-bumps on the connections to BGA 60 and PCB 62, thus allowing the stack of chips to be bonded very close together In accordance with the principles of the present invention, ceramic substrate 80 is formed to include a large number of through-vias 82, with the spacing between adjacent vias on the order of tens of microns or so (about 160 μm or so), thus forming a relatively “high density” interconnection structure. For example, a “controlled collapse chip connection” bump (referred to as a C4 bump) array 81 with a pitch on the order of about 160 μm may be suitable for this connection (which is similar in function to the well-known “flip-chip” type of interconnection).

FIG. 17 shows an alternative embodiment of the interconnection assembly of FIG. 16 (denoted here as interconnection assembly 300A). In this arrangement, a socket component 84 is used to provide the connection between ceramic substrate 80 and host PCB 62. As known in the art, socket component 84 may be configured to provide a releasable connection between components, allowing for different interconnection assemblies to be connected to PCB 62, as applications change from time to time. It is to be understood that interconnection assemblies 300, 300A typically include a heatsink element, similar to heatsink 70, described above in association with assemblies 100, 200, as well as perhaps other heat transfer elements, as necessary.

In the preceding, reference is made to embodiments presented in this disclosure. However, the scope of the present invention is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limited of the scope of the present invention. Thus, the preceding aspects, features, embodiments and advantages are merely illustrative and are not considered elements or limitations of the appended claims except where explicitly recited in a claim.

What is claimed is:

1. A high density optical-electrical interconnection arrangement comprising:
a substrate having a top major surface and an opposing bottom major surface, the substrate formed of a material exhibiting a high CTE to expedite heat transfer;
at least one electrical integrated circuit (EIC) disposed on the substrate and positioned in a central region of the top major surface;
a plurality of optical integrated circuits (OICs) disposed on the substrate so as to surround the at least one EIC to form a side-by-side configuration, each OIC including an optical connection array and an electrical connection array, with each OIC oriented such that the optical connection array disposed at periphery of the substrate top major surface and the electrical connection array disposed adjacent to the at least one EIC;
a plurality of bridging electrical connection modules, each bridging electrical connection module disposed to straddle an OIC and an EIC so as to contact the electrical connection array of the OIC and an associated electrical connection array on the at least one EIC; and
a heatsink disposed across at least a portion of the bottom major surface of the substrate for directing heat energy away from the interconnection arrangement.

2. A high density optical-electrical interconnection arrangement as defined in claim 1 wherein the plurality of OICs exhibit a height H1 greater than the height H2 of the at least one EIC, the high density optical-electrical interconnection arrangement further comprising
an interposer element disposed over an exposed top surface of the at least one EIC and formed of a thickness t substantially equal to the difference in height between the plurality of OICs and the at least one EIC, the interposer including a plurality of electrical connections formed therethrough, such that the plurality of bridging elements are disposed to contact the electrical connection array portions of the plurality of OICs and associated contacts on a top surface of the interposer, maintaining a planar structure.

3. A high density optical —electrical interconnection arrangement as defined in claim 1 wherein the arrangement further comprises an external electrical signal interface element disposed to providing electrical signal communication with the at least one EIC and an external host element.

4. The high density optical-electrical interconnection arrangement as defined in claim 3 wherein the external host element is an external PCB.

5. The high density optical-electrical interconnection arrangement as defined in claim 3 wherein the interface element comprises a ball grid array connector.

6. The high density optical-electrical interconnection arrangement as defined in claim 1 wherein each optical connection array portion comprises a fiber array connector.

7. The high density optical-electrical interconnection arrangement as defined in claim 6 wherein the substrate is formed to extend beyond the periphery of the plurality of OICs such that the plurality of fiber array connectors are positioned in a recessed configuration from the edges of the substrate.

8. The high density optical-electrical interconnection arrangement as defined in claim 1 wherein the substrate comprises silicon.

9. The high density optical-electrical interconnection arrangement as defined in claim 1 wherein
a first set of passive alignment fiducials are used to align the at least one EIC with the top major surface of the substrate;
a second set of passive alignment fiducials are used to align the plurality of OICs with the at least one EIC and the substrate; and
a third set of passive alignment fiducials are used to align the electrical connection arrays of the plurality of OICs with the electrical contact locations of the at least one EIC.

10. The high density optical-electrical interconnection arrangement as defined in claim 9 wherein at least the first set and the second set of alignment fiducials include fiducials etched into the top major surface of the silicon substrate.

11. The high density optical-electrical interconnection arrangement as defined in claim 1 wherein the arrangement further comprises
at least one heatsinking element disposed on an opposing exposed surface of a bridging electrical connection modules.
